(19) United States
(12) Patent Application Publication
(10) Pub. No.: US 2024/0081122 A1
(43) Pub. Date: Mar. 7, 2024

(54) DISPLAY SYSTEM INCLUDING PIXELATED COLOR CONVERSION MODULE

(71) Applicant: Meta Platforms Technologies, LLC, Menlo Park, CA (US)

(72) Inventors: Zhimin Shi, Bellevue, WA (US); Yun Wang, Bellevue, WA (US); Fenglin Peng, Redmond, WA (US); Christophe Antoine Hurni, Seattle, WA (US); James Ronald Bonar, Redmond, WA (US); Edward Buckley, High Peak (GB); Andrew John Ouderkirk, Kirkland, WA (US); Yongdan Hu, Bothell, WA (US)

(21) Appl. No.: 18/462,477

(22) Filed: Sep. 7, 2023

Related U.S. Application Data
(60) Provisional application No. 63/404,536, filed on Sep. 7, 2022.

(51) Int. Cl. H10K 59/38; H10K 59/50; H10K 59/80

(52) U.S. Cl. CPC H10K 59/38; H10K 59/50; H10K 59/878; H10K 59/879; H10K 59/8793

(57) ABSTRACT

A display system may include a light source that emits input light having a wavelength within a source wavelength range and an array of color conversion units overlapping a display area. A first set of color conversion units of the array of color conversion units may include a first color conversion medium that converts the input light to a first color of light having a wavelength within a first wavelength range that is different than the source wavelength range. The display system may also include a waveguide having an out-coupler that directs the input light from the light source toward the array of color conversion units. Various other devices, systems, and methods are also disclosed.

This application claims the benefit of U.S. Provisional Application No. 63/404,536, filed Sep. 7, 2022, the disclosure of which is incorporated, in its entirety, by this reference.

### BRIEF DESCRIPTION OF THE DRAWINGS

The accompanying drawings illustrate a number of example embodiments and are a part of the specification. Together with the following description, these drawings demonstrate and explain various principles of the present disclosure.

FIG. 1 is a diagram illustrating an exemplary display system, according to some embodiments.

FIG. 2 is a diagram illustrating an exemplary display system in accordance with various embodiments.

FIG. 3 is a diagram illustrating an exemplary display system in accordance with various embodiments.

FIG. 4 is a diagram illustrating an exemplary display system in accordance with various embodiments.

FIG. 5 is a diagram illustrating an exemplary display system in accordance with various embodiments.

FIG. 6 is a diagram illustrating an exemplary display system in accordance with various embodiments.

FIG. 7 is a diagram illustrating an exemplary display system in accordance with various embodiments.

FIG. 8A is a diagram illustrating an exemplary total internal reflection concentrator unit for display systems in accordance with various embodiments.

FIG. 8B is a diagram illustrating an exemplary total internal reflection concentrator unit for display systems m in accordance with various embodiments.

FIG. 9 is a flow diagram of an exemplary method for operating a display system according to some embodiments.

FIG. 10 is an illustration of exemplary augmented-reality glasses that may be used in connection with embodiments of this disclosure.

FIG. 11 is an illustration of an exemplary virtual-reality headset that may be used in connection with embodiments of this disclosure.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within this disclosure.

### DETAILED DESCRIPTION OF EXAMPLE EMBODIMENTS

Lasers may be utilized as light sources for display panels as they provide high brightness, high directionality, and a larger color gamut compared to conventional light-emitting diodes (LEDs), mini-LEDs, organic light-emitting diodes (OLEDs), and other light sources. Reflective display panels are common key component of a display engine. The reflective display panels may include, for example, liquid crystal on silicon (LCOS) displays, ferroelectric liquid crystal on silicon (FLCOS) displays, dot matrix displays (DMD), reflective thin film transistor (TFT) displays, etc. The delivery of light to a reflective display panel may occur through the use of a front light unit (FLU). A traditional FLU can include a beam splitter to separate the incident beam and the modulated output beam, which is typically bulky. Another common configuration may use oblique incidence angles to separate the incident and output beams from the display panel, but it also takes a lot of space. Furthermore, when the R/G/B light sources are separate, a color combiner (e.g., X-prism) is typically used, which may take additional space and weight. And the dispersive nature of some optics could further cause angular separation of different colors. Augmented-reality (AR) waveguides with a surface relief grating (SRG), volume Bragg grating (VBG), polarization volume hologram, or geometrical waveguide (WG) have more recently been proposed for use in forming compact FLUs. As a result, a compact and efficient FLU architecture is highly desired.

The present disclosure is generally directed to displays and illumination systems, devices, and methods that include waveguides with front-light units (FLUs) that use one or more light sources and pixelated color conversion modules to generate multiple colors (e.g., red, green, and blue colors) for a display panel. The light intensity of each pixel may be controlled by an integrated display panel (LCOS, FLCOS, TFT, etc.). The disclosed systems may include a light source, such as one or more pump light sources, a light distribution module, one or more color conversion modules, and a pixelated display engine. The integration of a pixelated color conversion module and the backplane of a display panel can greatly reduce the size and system assembly complexity.

Features from any of the embodiments described herein may be used in combination with one another in accordance with the general principles described herein. These and other embodiments, features, and advantages will be more fully understood upon reading the following detailed description in conjunction with the accompanying drawings and claims.

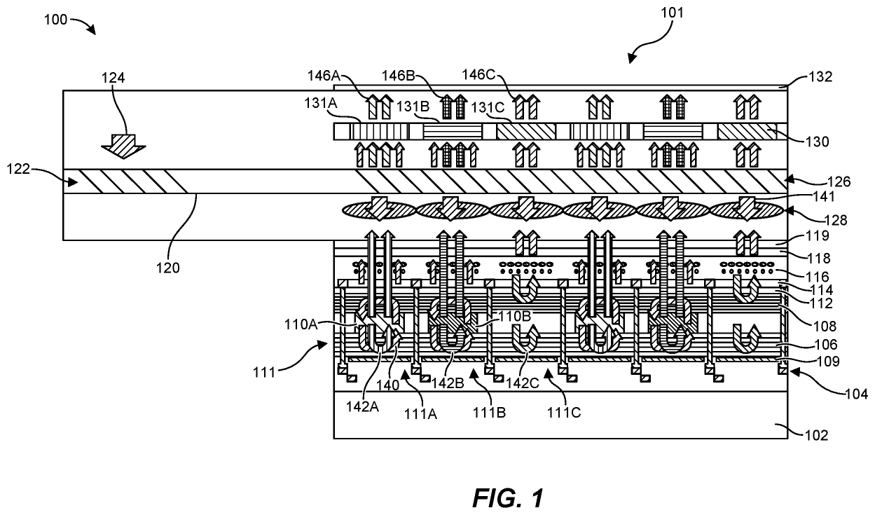

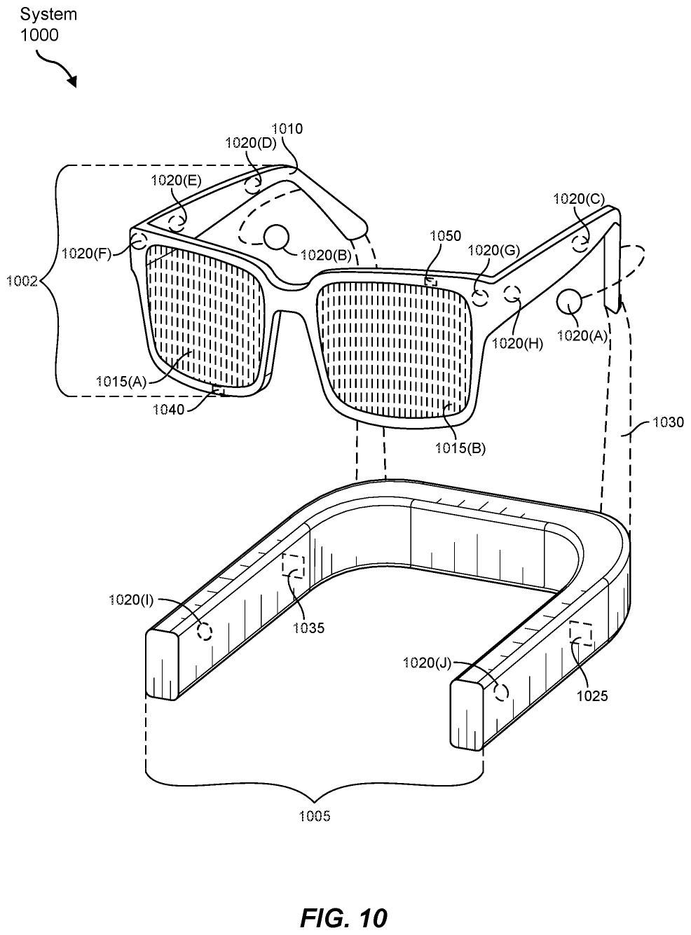

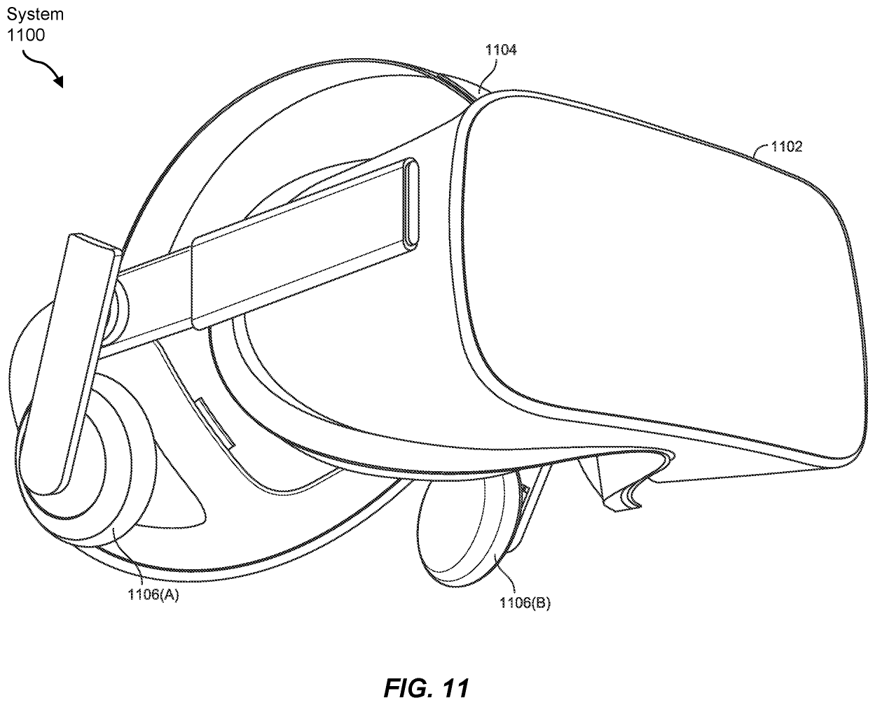

The following will provide, with reference to FIGS. 1-11, a detailed description of display systems and methods of manufacturing and using the same. The discussion associated with FIGS. 1-9 relates to the architecture, operation, and manufacturing of various example display systems and devices. The discussion associated with FIGS. 10 and 11 relates to exemplary virtual reality and augmented reality devices that may include display systems and devices as disclosed herein.

FIGS. 1-7 illustrate exemplary display systems in accordance with various embodiments. FIG. 1 illustrates a display system 100 that may be utilized in a front-light unit of a display panel. Display system 100 may utilize a colored light source, such as a blue light source, an ultraviolet (UV) light source, a near infrared (NIR) light source, and/or any other suitable color or wavelength light source. As shown, input blue light 124 may be received at an input coupler 122 of a waveguide 120 and may be output via an out-coupler 126 of waveguide 120 toward a color conversion/reflection region. Waveguide 120 may overlap a display area 101 of display system 100, as shown.

In some embodiments, input blue light may be used directly for blue pixels/sub-pixels of the display. For non-blue pixels, such as red and green pixels, the input blue light may be directed from out-coupler 126 through color-conversion mediums to convert the light the desired respective colors. Accordingly, blue light may be used to generate red/green (R/G) light, and it can be generalized to generate any set of multiple colors. “Pixel,” as used herein, may refer to a single pixel, sub-pixel, group of pixels (e.g., a group of RGB, RGBW, etc. sub-pixels collectively forming a pixel), or other pixel unit. The display configurations illustrated herein can use a wide selection of suitable light guiding and out-coupling mechanisms.

In at least one embodiment, out-coupled light 141 (e.g., blue light) from out-coupler 126 may pass to color conversion units 111, where out-coupled light is converted is converted to other suitable colors of light (e.g., red, green, etc.). In some examples, color conversion units 111 may be arranged to overlap corresponding pixels, with each color conversion unit 111 providing light for a corresponding color pixel of a display panel. In some examples, out-coupled light 141 may pass through an array of micro-focusing elements 128, such as an array of lenses, that each focus a portion of the out-coupled light 141 toward a corresponding color conversion unit 111.

As shown in FIG. 1, out-coupled light 141 may be respectively directed to color conversion units 111, including first color conversion units 111A, second color conversion units 111B, and third color conversion units 111C. Each of a first color conversion unit 111A, a second color conversion unit 111B, and a third color conversion unit 111C may correspond to a different color. For example, first color conversion units 111A may convert input blue light to red light, second color conversion units 111B may convert input blue light to green light, and third color conversion units 111C may reflect input blue light such that the blue light is emitted from third color conversion units 111C.

In some embodiments, display system 100 may also include a light modulation layer 116 that includes a liquid crystal layer and/or another suitable light modulation medium. Light modulation layer 116 (e.g., a liquid crystal layer) may be disposed between a common electrode 118 and an array of pixel electrodes 114 for blocking or allowing passage of light through corresponding pixel regions of display system 100. Pixel electrodes 114 may be controlled by, for example, controlling electronics that selectively apply various levels of voltage to individual pixel electrodes to generate an image with colored light from color conversion units 111. Accordingly, light may be blocked by light modulation layer 116 to a desired degree at each pixel of display system 100 such that a desired amount of light passes into and is emitted by each color conversion unit 111 on a pixel-by-pixel basis. Thus, light modulation layer 116 may enable formation of a desired image on a display screen of display system 100.

Color conversion units 111 used to convert light to another color (e.g., first color conversion units 111A and second color conversion units 111B) may each contain one or a combination of color-conversion materials that can absorb light within a certain wavelength range and emit light in a desired wavelength range. Such color-conversion materials may include, for example, quantum dot materials, fluorescent materials, quantum well materials, semiconductor nanowire materials, and/or any other suitable color-converting materials.

In some embodiments, each of color conversion units 111 may also contain one or more of the following: (1) high/partial reflective (HR/PR) film stacks to form a resonant cavity for the pump light (e.g., blue, UV, NIR, etc.) to enhance absorption, and consequently, conversion efficiency, (2) HR/PR film stacks to form a resonant cavity for the converted light to better control its spectral and angular profile, and (3) polarizers (e.g., wire-grid, particle, multi-stack, reflective polarizers, etc.). In at least one example, a reflective polarizer may be utilized with a waveplate and reflective coatings to recycle color-converted light having unwanted polarization states so as to improve overall light extraction efficiency.

As shown in FIG. 1, out-coupled light 141 may pass into color conversion units 111. Each first color conversion unit 111A may include a first color conversion medium 110A and each second color conversion unit 111B may include a second color conversion medium 110B. Out-coupled light 141 (e.g., blue, UV, NIR, etc.) passing through first and second color conversion units 111A and 111B may be converted to respective colors. In the example shown, out-coupled light 141 may include a blue wavelength(s) light. At least some pixels/subpixels of display system 100 may be overlapped by color conversion units 111C such that blue light passes through without experiencing changes in wavelength. Accordingly, blue light in these pixel regions may be pass through color conversion units 111C and be emitted as blue light in those pixel regions. Blue light passing into first color conversion units 111A may be converted by first color conversion medium 110A to another wavelength(s), such as light in a red wavelength range. Blue light passing into second color conversion units 111B may be converted by second color conversion medium 110B to an additional wavelength(s), such as light in a green wavelength range.

As shown in FIG. 1, at least some amount of blue light may pass through first and second color conversion mediums 110A and 110B without being converted during an initial pass. According to some examples, light may be internally reflected within first and second color conversion units 111A and 111B to increase the quantity of light converted. As shown, for example, in FIG. 1, color conversion units 111 may further include a first reflective stack 106 and a second reflective stack 108 overlapping first and second color conversion mediums 110A and 110B, with first and second color conversion mediums 110A disposed between first and second reflective stacks 106 and 108. In at least one embodiment, first reflective stack 106 may be disposed on a side nearest a substrate 102 and second reflective stack 108 may be disposed on an opposite side nearest out-coupler 126. First and second reflective stacks 106 and 108 may together form, for example, a resonant cavity that includes the first and second color conversion mediums 110A and 110B. In some examples, first reflective stack 106 may be disposed on a reflective surface 109 that reflects any light passing through first reflective stack 106. First and second stacks 106 and 108 may each, for example, comprise multilayer stacks of alternating high- and low-index films.

In this example, first and second reflective stacks 106 and 108 may selectively reflect light within resonant cavities of color conversion units 111 to enhance conversion efficiency of blue light into green and/or red light. For example, second reflective stack 108 may be partially reflective with respect to blue light, enabling a significant proportion of out-coupled blue light to enter into the resonant cavity. First reflective stack 106 may be highly reflective with respect to a broad range of wavelengths, such as all or a substantial portion of visible wavelengths of light, including red, green, and blue light. Accordingly, substantially all blue light light passing unconverted through first and second color conversion mediums 110A and 110B may be reflected back as reflected blue light 140 towards first and second color conversion mediums 110A and 110B and second reflective stack 108. Subsequently, second reflective stack 108 may reflect a significant proportion of the recycled blue light back again through first and second color conversion mediums 110A and 110B, where additional blue light is converted to green and red light. As such, additional blue light may be recycled and converted to green and red light within first and second color conversion mediums 110A and 110B. Red light and green light may also be reflected by first reflective stack 106 as reflected red light 142A and reflected green light 142B such that these colors of light are directed back out of color conversion units 111 toward a display region of display system 100. Red and green wavelengths of light may pass through second reflective stack 108 with high efficiency in each of color conversion units 111 since second reflective stack 108 selectively reflects primarily blue wavelengths of light. Blue light passing to color conversion unit 111C may remain unconverted and may be reflected by first reflective stack 106 and/or second reflective stack 108 as reflected blue light 142C, as shown in FIG. 1.

In some examples, display system 100 may also include one or more polarizers, such as reflective polarizers, absorbing polarizers, and/or any other suitable types of polarizers, that permit passage of light having a selected polarization state and/or reflect and recycle light within color conversion units 111 that does not have the selected polarization state. For example, display system 100 may include a polarizer 119 and/or a polarizer 112 disposed on opposite side of the modulation medium. Polarizers 112 and/or 119 may include any suitable type of polarizer, such as a wire-grid polarizer, a multi-stack polarizer, and/or a reflective polarizer. Light having an undesired polarization state may be returned to color conversion units 111, where the light is internally reflected until it is in a desired polarization state. In at least one example, polarizer 112 may include multiple layered polarizers, such as a reflective polarizer below an absorbing polarizer for better light-recycling and conversion efficiency to produce light having a desired polarization state.

Light output from color conversion units 111 and passing through polarizers 112 and 119 may then be directed toward corresponding pixel regions of a color filter layer 130. Color filter layer 130 may filter out unwanted wavelengths of light, such as blue light, in various pixels so that only or primarily desired colors are emitted from respective pixels. Color filter layer 130 may include, for example, first color filters 131A, second color filters 131B, and third color filters 131C respectively overlapping first color conversion units 111A, second color conversion units 111B, and third color conversion units 111C. In at least one example, first output light 146A, such as red light, may be emitted from first color filters 131A, second output light 146B, such as green light, may be emitted from second color filters 131B, and third output light 146C, such as blue light, may be emitted from third color filters 131C. In some examples light emitted from color filter layer 130 may additionally pass through an optional polarizer 132 prior to exiting display system 100.

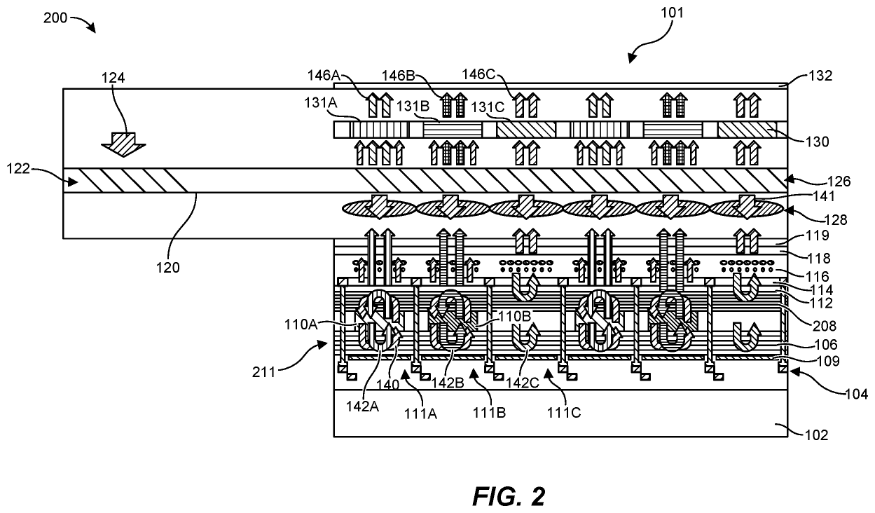

FIG. 2 illustrates a display system 200, according to some embodiments. As shown, display system 200 includes a second reflective stack 208. In contrast to second reflective stack 108 of display system 100 in FIG. 1, which is partially reflective with respect to the incoming pump light (e.g., blue light, UV light, NIR light, etc.) output from out-coupler 126, second reflective stack 208 in FIG. 2 is partially reflective with respect to all or a substantial portion of the visible light spectrum, including red, green, and blue wavelengths of light. Accordingly, pump light, such as blue wavelength light, that is converted to other colors of light, such as red and green light, may be recycled within corresponding resonant cavities of color conversion units 211 before being emitted. Such resonant cavities may thus enable further control of the spectral and angular profile of the converted light and the emitted pump light. Additionally, in some examples, color conversion units 211 may form optically pumped lasers for the converted colors of light using the pump light.

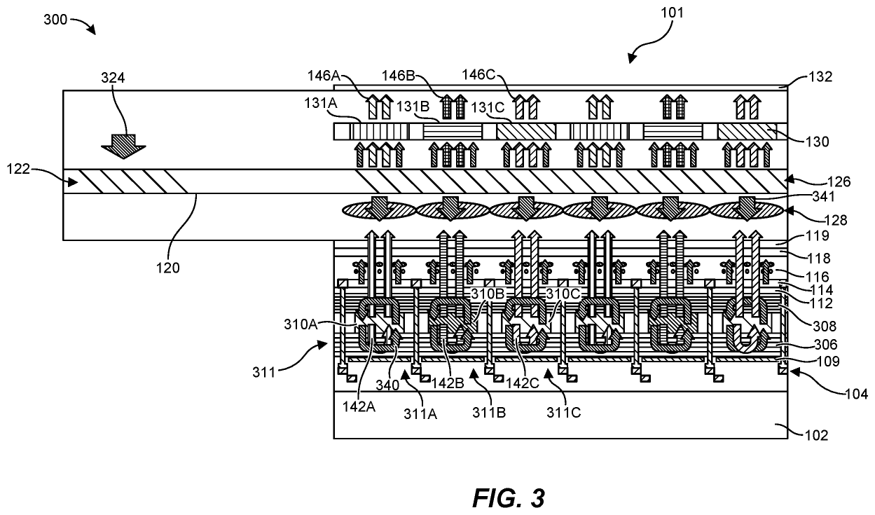

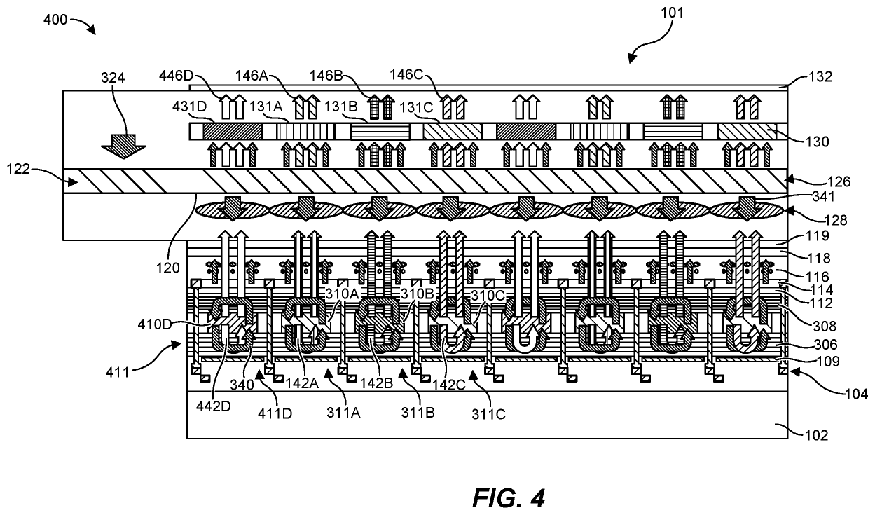

FIG. 3 illustrates a display system 300, according to some embodiments. This configuration uses, for example, a non-blue and/or substantially nonvisible color of pump light (e.g., UV light, NIR light, etc.). Because a display color of light, such as blue, is not utilized as the pump light, three color-conversion mediums may be utilized to create desired red, green, and blue (R/G/B) and/or any other desired colors for the display. In some examples, color-conversion mediums may additionally or alternatively be used to generate white light for certain additional pixels (e.g., in a four-color pixel display as shown in FIG. 4).

In at least one embodiment, as shown in FIG. 2, input UV light 324 may be received at input coupler 122 of a waveguide 120 and may be output via out-coupler 126 as out-coupled UV light 341 toward color conversion units 311, including first color conversion units 311A, second color conversion units 311B, and third color conversion units 311C. Each of a first color conversion unit 311A, a second color conversion unit 311B, and a third color conversion unit 311C may respectively correspond to a different color. For example, first color conversion units 311A may convert input UV light to red light, second color conversion units 311B may convert input UV light to green light, and third color conversion units 311C may convert input UV light to blue light.

As shown in FIG. 3, out-coupled light 341 may pass into color conversion units 311. Each first color conversion unit 311A may include a first color conversion medium 310A, each second color conversion unit 311B may include a second color conversion medium 3106, and each third color conversion unit 311C may include a third color conversion medium 310C. Out-coupled light 341 (e.g., UV, NIR, etc. pump light) passing through color conversion units 311 may be converted to respective colors. In the example shown, out-coupled light 341 may include a UV wavelength(s) light. Pump light, such as UV light, passing into first color conversion units 311A may be converted by first color conversion medium 310A to another wavelength(s), such as light in a red wavelength range. Pump light passing into second color conversion units 311B may be converted by second color conversion medium 3106 to an additional wavelength(s), such as light in a green wavelength range. Further, pump light passing into third color conversion units 311C may be converted by third color conversion medium 3106 to an additional wavelength(s), such as light in a blue wavelength range. First and second reflective stacks 306 and 308 may selectively reflect light within resonant cavities of color conversion units 311 to enhance conversion efficiency of UV light into green, red, and/or blue light. For example, second reflective stack 308 may be partially reflective with respect to UV light, enabling a significant proportion of out-coupled UV light to enter into the resonant cavity. First reflective stack 306 may be highly reflective with respect to all or a substantial portion red, green, and blue light as well as the pump light (e.g., UV light). Accordingly, substantially all UV light light passing unconverted through first, second, and third color conversion mediums 110A, 110B, and 110C may be reflected back as reflected UV light 340 towards first and second color conversion mediums 310A and 310B and second reflective stack 308.

FIG. 4 illustrates a display system 400, according to some embodiments. In the example illustrated in FIG. 4, display system 400 may utilize an additional color conversion unit such that four color-conversion mediums are used to convert the pump light into (e.g., UV light) into four separate colors of display light, such as red, green, blue, and white light (R/G/B/W). This configuration can also be generalized to generate any set of multiple colors.

As shown in FIG. 4, out-coupled light 341 may pass into color conversion units 411. Each first color conversion unit 311A may include a first color conversion medium 310A, each second color conversion unit 311B may include a second color conversion medium 310B, and each third color conversion unit 311C may include a third color conversion medium 310C, as shown, for example, in FIG. 3. Additionally, color conversion units 411 may also include fourth color conversion units 411D that include a fourth color conversion medium 410D. Pump light, such as UV light, passing into fourth color conversion units 411D may be converted by fourth color conversion medium 410D to another wavelength(s), such as light including a range of wavelengths that are visible as white light 442D. In at least one example, a fourth output light 446D, such as white light from fourth color conversion units 411D, may be emitted from fourth color filters 431D.

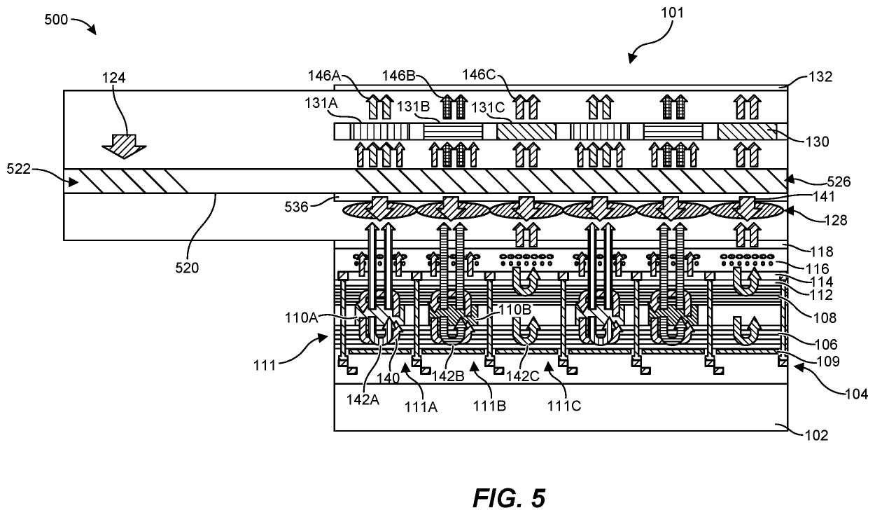

FIG. 5 illustrates a display system 500, according to some embodiments. This configuration is an example of a display system (see, e.g., display system 100 in FIG. 1) in which the system uses geometric waveguide out-coupling prisms and reflective polarizers. The use of a reflective polarizer and some waveplates can implement polarization recycling to enhance the light extraction efficiency. For example, display system 500 may include a waveguide 520 having an input coupler 522 and an out-coupler 526. According to at least one example, out-coupler 526 may include geometric waveguide out-coupling prisms. Additionally or alternatively, waveguide 520 may include, for example, a volume-Bragg grating input coupler 522 and/or out-coupler 526. A reflective polarizer 536 may be disposed at or near an output surface of out-coupler 526 such that light from out-coupler 526 that is not in a desired polarized state may be reflected and recycled to enhance efficiency in emitting light having a desired polarization state.

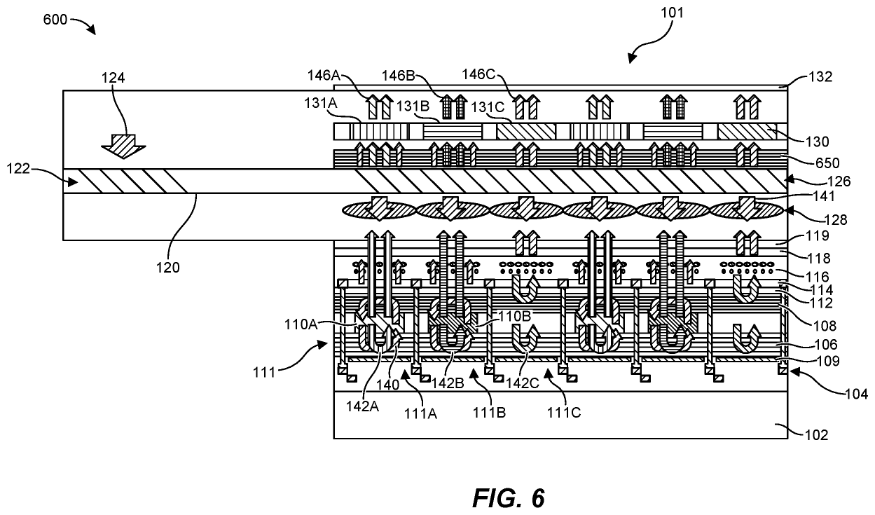

FIG. 6 illustrates a display system 600, according to some embodiments. As shown, this configuration adds a high reflectance (HR) stack for pump light (e.g., blue light) light for improved light efficiency. As shown, in contrast to previously-described displays, display system 600 includes a third reflective stack 650 that is highly reflective with respect to the incoming pump light (e.g., blue light, UV light, NIR light, etc.). Accordingly, pump light reaching third reflective stack 650 may be reflected back towards color conversion units 111 and may be further recycled and converted to desired colors of light, such as red and green light.

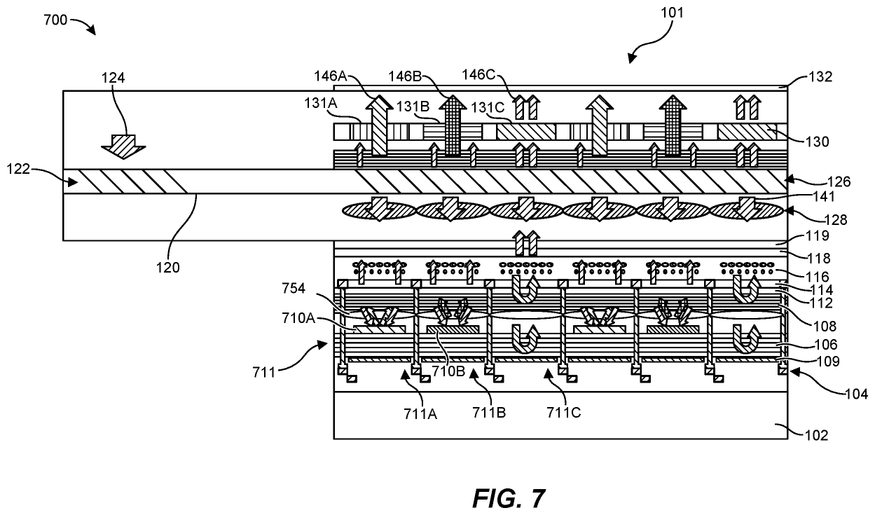

FIG. 7 illustrates a display system 700, according to some embodiments. As shown, this configuration adds a lens array (i.e., micro-focusing elements) to focus light onto wavelength conversion layers to improve collection efficiency. In at least one example, display system 700 may include color conversion units 711 that each include a micro-focusing element 754, such as a micro-lens, that focuses light on a corresponding color conversion mediums, such as first and second color conversion mediums 710A and 710B of first and second color conversion units 711A and 711B. A micro-focusing element 754 may also focus light (e.g., blue light) within third color conversion units 711C, which may not include a color conversion medium. In addition to the illustrated configuration, such micro-focusing elements can also be used with other source light(s) (e.g., UV, NIR) and to generate other colors of light (R/G/B, R/G/B/W, etc.).

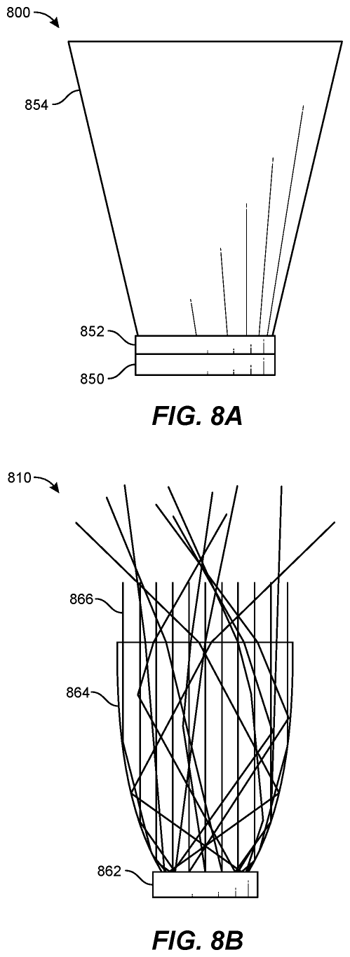

FIGS. 8A and 8B illustrate exemplary total internal reflection (TIR) concentrator units that may be utilized in display systems, as disclosed herein. As shown in FIG. 8A, a TIR concentrator unit 800 may include a TIR concentrator 854 that directs light toward a wavelength converter 852, which may include a color conversion medium in accordance with any of the examples described herein. A back reflector 850 may be disposed on an opposite side of wavelength converter 852 to reflect light back towards wavelength converter 852 for output and/or recycling of the light. As shown in FIG. 8B, a TIR concentrator unit 810 may include a TIR concentrator 864 that directs light toward a wavelength converter 862. A back reflector 860, such as a reflective layer, may be disposed on an opposite side of wavelength converter 862 to reflect light back towards wavelength converter 862 for output and/or recycling of the light. The illustrated TIR concentrator units 800 and 810 may be utilized in any of the display systems described herein to provide higher efficiency wavelength conversion in color conversion units of the display systems. In some examples, a TIR concentrator may be used in combination with a geometric lens to enhance converted light collection.

Light sources utilized in the disclosed embodiments may include one or more colors/wavelengths of the following from one or more (pump) light sources: 1) Lasers, such as VCSELs, edge-emitting lasers (EELS), fiber lasers, diode lasers, 2) light-emitting diodes (LEDs), superluminescent diodes (SLEDS), and/or organic light-emitting diodes (OLEDs), and/or 3) nonlinear converted light sources, such as second-harmonic generation (SHG), third-harmonic generation (THG), four-wave mixing FWM, etc.

Light delivery, as described herein, can be accomplished through one or a combination of the following types of waveguides: 1) a thick waveguide slab (layered medium with different intrinsic or effective optical refractive indices), 2) a single-mode or a few mode waveguide slab, 3) a single-mode or a few mode waveguide array (each waveguide would deliver light to one column).

An In/Out coupling mechanism, as disclosed, may include one or more of the following: 1) a geometrical waveguide coupler, 2) surface relief gratings, 3) volume Bragg gratings, 4) a PVH and/or holographic optical element (HOE), and/or metamaterials.

Color conversion modules, as described herein, may include one or a combination of color-conversion materials that can absorb light within a certain wavelength range, and emit light in the desired wavelength range, such as quantum dots, fluorescent materials, quantum wells, semiconductor nanowires, etc. The color conversion modules can also contain high/partial reflective (HR/PR) film stacks to form a resonant cavity for the pump (blue) light to enhance absorption and consequently conversion efficiency. The HR/PR film stacks may also form a resonant cavity for the converted light to control its spectral and angular profile. In some examples, the color conversion modules may include polarizers (e.g., wire-grid, particle, multi-stack, reflective polarizer, etc.). The reflective polarizers, utilized with waveplates and reflective coatings, can recycle the color-converted light in the unwanted polarization, thereby improving light extraction efficiency.

The disclosed light modulation modules may be used with a variety of reflective display systems, including, for example, LCOS, FCOS, TFT-LC, polymer-based electro-optic (EO), and organic semiconductor material-based display panels. In a pixelated display panel, each pixel may include one or a combination of the following light modulation mechanisms: 1) active optical materials (e.g., EO polymers, organic semiconductor materials, EO materials, 2D materials, ITO) that can modify their optical response by an electric field or current, and/or 2) structures that can modify the optical response by an electric field or current.

In regards to additional components that may be included in the disclosed display systems, each polarizer may include one or a combination of an absorbing polarizer (e.g, wiregrid, nano-particles, etc.) and a reflective polarizer (e.g., dielectric stacks, LC-polymer film, etc.). Each color filter can include a combination of an absorptive color filter and/or a reflective color filter (which can reflect the pump light to increase the contrast and/or color gamut). In case of a separate color (UV) pump light, the color filters may not need to be patterned and may primarily function to absorb or reflect UV light. Micro-focusing elements, as described herein, can include one or a combination of a micro-lens array, a gradient index micro-lens, diffractive optical elements, a meta-lens, and/or a layered structure with effective focusing power.

In order to create a super-compact display, it may be beneficial to put some of a display pipeline logic into the pixel circuit. For example, dither logic may be utilized in some examples because 1) most displays are capable of 8 bit greyscale, 2) graphics pipeline operations are usually >13 bit, and 3) dithering is typically required to render >13 bits on <8 bit display. Dithering may be the last step in the pipeline and it is conventionally handled in the chipset prior to transmission over the display interface. However, conventionally-generated dithered images may be less compressible due to added noise. In contrast, if dither logic were incorporated into the pixel circuit, compressed data might be transmitted to the display and decompressed at the display periphery. Then dithering might be performed at the pixel circuit level. This might result in significantly reduced display bandwidth. Additionally, dithering may be a simple threshold operation that could feasibly be done in a complementary metal-oxide semiconductor (CMOS) pixel. In some example, late-stage warp may be put into the pixel logic if the display device is field-sequential. Warp may be different for each color channel for a color-sequential display. Shearing correction may be required for rolling-shutter type displays. Accordingly, a simply left-right translation, or perhaps a shear, may be readily achieved on the backplane, rather than in the pipeline.

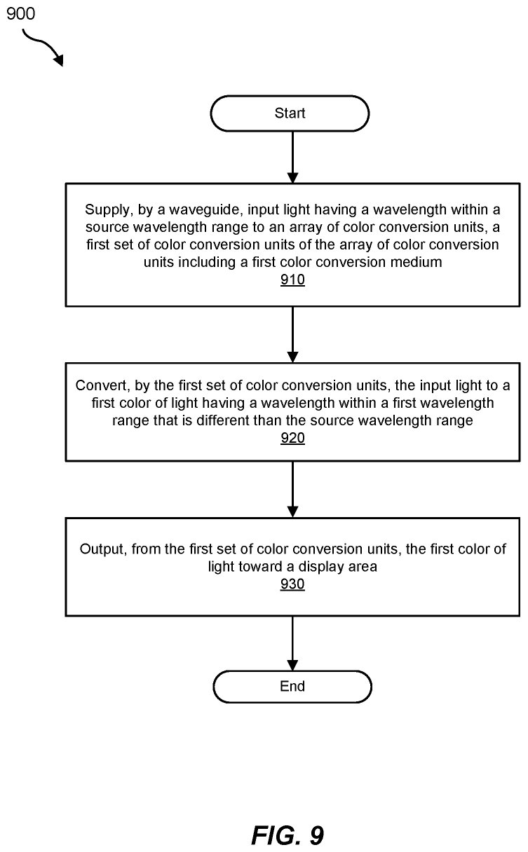

FIG. 9 is a flow diagram illustrating a method 900 of fabricating a display system according to at least one embodiment of the present disclosure. As illustrated in FIG. 9, at operation 910, input light having a wavelength within a source wavelength range may be supplied by a waveguide to an array of color conversion units. In this example, a first set of color conversion units of the array of color conversion units may include a first color conversion medium.

At operation 920, the input light may be converted, by the first set of color conversion units, to a first color of light having a wavelength within a first wavelength range that is different than the source wavelength range.

At operation 930, the first color of light may be output, from the first set of color conversion units, toward a display area.

Accordingly, the present disclosure includes display systems, devices, and methods that include waveguides with front-light units (FLUS) that may utilize one or more light sources and pixelated color conversion modules to generate multiple colors (e.g., red, green, and blue colors) for a display panel. The light intensity of each pixel may be controlled by an integrated display panel (LCOS, FLCOS, TFT, etc.). The disclosed systems may include a light source, such as one or more pump light sources, a light distribution module, one or more color conversion modules, and a pixelated display engine. The integration of pixelated color conversion units with the backplane of a display panel can greatly reduce the size and system assembly complexity, facilitating the use of such display system in a variety of devices, including devices, such as augmented reality headsets, requiring relatively small components. The disclosed display systems may also provide high light efficiency by enabling selective recycling and of pump light within color conversion units to provide high light throughput in various colors at a pixel level.

### EXAMPLE EMBODIMENTS

Example 1: A display system includes a light source that emits input light having a wavelength within a source wavelength range and an array of color conversion units overlapping a display area. A first set of color conversion units of the array of color conversion units includes a first color conversion medium that converts the input light to a first color of light having a wavelength within a first wavelength range that is different than the source wavelength range. The display system additionally includes a waveguide having an out-coupler that directs the input light from the light source toward the array of color conversion units.

Example 2: The display system of Example 1, where a second set of color conversion units of the array of color conversion units includes a second color conversion medium that converts the input light to a second color of light having a wavelength within a second wavelength range that is different than each of the first wavelength range and the source wavelength range.

Example 3: The display system of any of Examples 1 and 2, where the color conversion units are arrayed such that each color conversion unit overlaps a corresponding pixel of an array of pixels.

Example 4: The display system of any of Examples 1-3, where the input light includes blue color light.

Example 5: The display system of Example 4, where a third set of color conversion units of the array of color conversion units reflect the input light toward the display area without passing the input light through a color conversion medium.

Example 6: The display system of any of Examples 1-3, where the input light includes ultraviolet light.

Example 7: The display system of any of Examples 1-6, where the waveguide overlaps the display area such that the waveguide is disposed between the display area and the array of color conversion units.

Example 8: The display system of any of Examples 1-7, further including a color filter layer overlapping the array of color conversion modules such that converted light passes through color filters of the color filter layer.

Example 9: The display system of any of Examples 5-8, further including an array of micro-focusing elements, where each micro-focusing element of the array of micro-focusing elements overlaps a corresponding color conversion unit of the array of color conversion units and directs a portion of the light from the waveguide toward the corresponding color conversion unit.

Example 10: The display system of any of Examples 1-9, where each color conversion unit of the array of color conversion units includes at least a portion of a first reflective stack and at least a portion of a second reflective stack.

Example 11: The display system of 10, where i) one of the first reflective stack and the second reflective stack includes a highly reflective stack with respect to a broad range of wavelengths, and ii) the other of the first reflective stack and the second reflective stack includes a partially reflective stack with respect to a narrower range of wavelengths that includes the source wavelength range.

Example 12: The display system of Example 10, where i) one of the first reflective stack and the second reflective stack includes a highly reflective stack with respect to a broad range of wavelengths, and ii) the other of the first reflective stack and the second reflective stack includes a partially reflective stack with respect to a broad range of wavelengths.

Example 13: The display system of any of Examples 1-12, further including at least one polarizer disposed between the waveguide and the array of color conversion units.

Example 14: The display system of any of Examples 1-13, further including a light modulation layer disposed between the waveguide and the array of color conversion units.

Example 15: The display system of Example 14, further including a common electrode disposed on a first side of the light modulation layer and an array of pixel electrodes disposed on an opposite side of the light modulation layer.

Example 16: A color conversion unit includes i) a color conversion medium that converts input light having a wavelength within a source wavelength range to a first color of light having a wavelength within a first wavelength range that is different than the source wavelength range, ii) a first reflective stack disposed on a first side of the color conversion medium, and iii) a second reflective stack disposed on a second side of the color conversion medium, wherein at least one of the first reflective stack and the second reflective stack includes a highly reflective stack with respect to a broad range of wavelengths.

Example 17: The color conversion unit of Example 16, where the other of the first reflective stack and the second reflective stack includes a partially reflective stack with respect to a range of wavelengths that includes the source wavelength range.

Example 18: The color conversion unit of Example 16, where the other of the first reflective stack and the second reflective stack includes a partially reflective stack with respect to a broad range of wavelengths.

Example 19: The color conversion unit of any of Examples 16-18, where at least one of the first reflective stack and the second reflective stack includes a multilayer stack of alternating high- and low-index films.

Example 20: A method includes i) supplying, by a waveguide, input light having a wavelength within a source wavelength range to an array of color conversion units, wherein a first set of color conversion units of the array of color conversion units includes a first color conversion medium, ii) converting, by the first set of color conversion units, the input light to a first color of light having a wavelength within a first wavelength range that is different than the source wavelength range, and iii) outputting, from the first set of color conversion units, the first color of light toward a display area.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., augmented-reality system 1000 in FIG. 10) or that visually immerses a user in an artificial reality (such as, e.g., virtual-reality system 1100 in FIG. 11). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 10, augmented-reality system 1000 may include an eyewear device 1002 with a frame 1010 configured to hold a left display device 1015(A) and a right display device 1015(B) in front of a user's eyes. Display devices 1015(A) and 1015(B) may act together or independently to present an image or series of images to a user. While augmented-reality system 1000 includes two displays, embodiments of this disclosure may be implemented in augmented-reality systems with a single NED or more than two NEDs.

In some embodiments, augmented-reality system 1000 may include one or more sensors, such as sensor 1040. Sensor 1040 may generate measurement signals in response to motion of augmented-reality system 1000 and may be located on substantially any portion of frame 1010. Sensor 1040 may represent one or more of a variety of different sensing mechanisms, such as a position sensor, an inertial measurement unit (IMU), a depth camera assembly, a structured light emitter and/or detector, or any combination thereof. In some embodiments, augmented-reality system 1000 may or may not include sensor 1040 or may include more than one sensor. In embodiments in which sensor 1040 includes an IMU, the IMU may generate calibration data based on measurement signals from sensor 1040. Examples of sensor 1040 may include, without limitation, accelerometers, gyroscopes, magnetometers, other suitable types of sensors that detect motion, sensors used for error correction of the IMU, or some combination thereof.

In some examples, augmented-reality system 1000 may also include a microphone array with a plurality of acoustic transducers 1020(A)-1020(J), referred to collectively as acoustic transducers 1020. Acoustic transducers 1020 may represent transducers that detect air pressure variations induced by sound waves. Each acoustic transducer 1020 may be configured to detect sound and convert the detected sound into an electronic format (e.g., an analog or digital format). The microphone array in FIG. 10 may include, for example, ten acoustic transducers: 1020(A) and 1020(B), which may be designed to be placed inside a corresponding ear of the user, acoustic transducers 1020(C), 1020(D), 1020(E), 1020(F), 1020(G), and 1020(H), which may be positioned at various locations on frame 1010, and/or acoustic transducers 1020(1) and 1020(J), which may be positioned on a corresponding neckband 1005.

In some embodiments, one or more of acoustic transducers 1020(A)-(J) may be used as output transducers (e.g., speakers). For example, acoustic transducers 1020(A) and/or 1020(B) may be earbuds or any other suitable type of headphone or speaker.

The configuration of acoustic transducers 1020 of the microphone array may vary. While augmented-reality system 1000 is shown in FIG. 10 as having ten acoustic transducers 1020, the number of acoustic transducers 1020 may be greater or less than ten. In some embodiments, using higher numbers of acoustic transducers 1020 may increase the amount of audio information collected and/or the sensitivity and accuracy of the audio information. In contrast, using a lower number of acoustic transducers 1020 may decrease the computing power required by an associated controller 1050 to process the collected audio information. In addition, the position of each acoustic transducer 1020 of the microphone array may vary. For example, the position of an acoustic transducer 1020 may include a defined position on the user, a defined coordinate on frame 1010, an orientation associated with each acoustic transducer 1020, or some combination thereof.

Acoustic transducers 1020(A) and 1020(B) may be positioned on different parts of the user's ear, such as behind the pinna, behind the tragus, and/or within the auricle or fossa. Or, there may be additional acoustic transducers 1020 on or surrounding the ear in addition to acoustic transducers 1020 inside the ear canal. Having an acoustic transducer 1020 positioned next to an ear canal of a user may enable the microphone array to collect information on how sounds arrive at the ear canal. By positioning at least two of acoustic transducers 1020 on either side of a user's head (e.g., as binaural microphones), augmented-reality device 1000 may simulate binaural hearing and capture a 3D stereo sound field around about a user's head. In some embodiments, acoustic transducers 1020(A) and 1020(B) may be connected to augmented-reality system 1000 via a wired connection 1030, and in other embodiments acoustic transducers 1020(A) and 1020(B) may be connected to augmented-reality system 1000 via a wireless connection (e.g., a BLUETOOTH connection). In still other embodiments, acoustic transducers 1020(A) and 1020(B) may not be used at all in conjunction with augmented-reality system 1000.

Acoustic transducers 1020 on frame 1010 may be positioned in a variety of different ways, including along the length of the temples, across the bridge, above or below display devices 1015(A) and 1015(B), or some combination thereof. Acoustic transducers 1020 may also be oriented such that the microphone array is able to detect sounds in a wide range of directions surrounding the user wearing the augmented-reality system 1000. In some embodiments, an optimization process may be performed during manufacturing of augmented-reality system 1000 to determine relative positioning of each acoustic transducer 1020 in the microphone array.

In some examples, augmented-reality system 1000 may include or be connected to an external device (e.g., a paired device), such as neckband 1005. Neckband 1005 generally represents any type or form of paired device. Thus, the following discussion of neckband 1005 may also apply to various other paired devices, such as charging cases, smart watches, smart phones, wrist bands, other wearable devices, hand-held controllers, tablet computers, laptop computers, other external compute devices, etc.

As shown, neckband 1005 may be coupled to eyewear device 1002 via one or more connectors. The connectors may be wired or wireless and may include electrical and/or non-electrical (e.g., structural) components. In some cases, eyewear device 1002 and neckband 1005 may operate independently without any wired or wireless connection between them. While FIG. 10 illustrates the components of eyewear device 1002 and neckband 1005 in example locations on eyewear device 1002 and neckband 1005, the components may be located elsewhere and/or distributed differently on eyewear device 1002 and/or neckband 1005. In some embodiments, the components of eyewear device 1002 and neckband 1005 may be located on one or more additional peripheral devices paired with eyewear device 1002, neckband 1005, or some combination thereof.

Pairing external devices, such as neckband 1005, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 1000 may be provided by a paired device or shared between a paired device and an eyewear device, thus reducing the weight, heat profile, and form factor of the eyewear device overall while still retaining desired functionality. For example, neckband 1005 may allow components that would otherwise be included on an eyewear device to be included in neckband 1005 since users may tolerate a heavier weight load on their shoulders than they would tolerate on their heads. Neckband 1005 may also have a larger surface area over which to diffuse and disperse heat to the ambient environment. Thus, neckband 1005 may allow for greater battery and computation capacity than might otherwise have been possible on a stand-alone eyewear device. Since weight carried in neckband 1005 may be less invasive to a user than weight carried in eyewear device 1002, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 1005 may be communicatively coupled with eyewear device 1002 and/or to other devices. These other devices may provide certain functions (e.g., tracking, localizing, depth mapping, processing, storage, etc.) to augmented-reality system 1000. In the embodiment of FIG. 10, neckband 1005 may include two acoustic transducers (e.g., 1020(1) and 1020(J)) that are part of the microphone array (or potentially form their own microphone subarray). Neckband 1005 may also include a controller 1025 and a power source 1035.

Acoustic transducers 1020(1) and 1020(J) of neckband 1005 may be configured to detect sound and convert the detected sound into an electronic format (analog or digital). In the embodiment of FIG. 10, acoustic transducers 1020(1) and 1020(J) may be positioned on neckband 1005, thereby increasing the distance between the neckband acoustic transducers 1020(1) and 1020(J) and other acoustic transducers 1020 positioned on eyewear device 1002. In some cases, increasing the distance between acoustic transducers 1020 of the microphone array may improve the accuracy of beamforming performed via the microphone array. For example, if a sound is detected by acoustic transducers 1020(C) and 1020(D) and the distance between acoustic transducers 1020(C) and 1020(D) is greater than, e.g., the distance between acoustic transducers 1020(D) and 1020(E), the determined source location of the detected sound may be more accurate than if the sound had been detected by acoustic transducers 1020(D) and 1020(E).

Controller 1025 of neckband 1005 may process information generated by the sensors on neckband 1005 and/or augmented-reality system 1000. For example, controller 1025 may process information from the microphone array that describes sounds detected by the microphone array. For each detected sound, controller 1025 may perform a direction-of-arrival (DOA) estimation to estimate a direction from which the detected sound arrived at the microphone array. As the microphone array detects sounds, controller 1025 may populate an audio data set with the information. In embodiments in which augmented-reality system 1000 includes an inertial measurement unit, controller 1025 may compute all inertial and spatial calculations from the IMU located on eyewear device 1002. A connector may convey information between augmented-reality system 1000 and neckband 1005 and between augmented-reality system 1000 and controller 1025. The information may be in the form of optical data, electrical data, wireless data, or any other transmittable data form. Moving the processing of information generated by augmented-reality system 1000 to neckband 1005 may reduce weight and heat in eyewear device 1002, making it more comfortable to the user.

Power source 1035 in neckband 1005 may provide power to eyewear device 1002 and/or to neckband 1005. Power source 1035 may include, without limitation, lithium ion batteries, lithium-polymer batteries, primary lithium batteries, alkaline batteries, or any other form of power storage. In some cases, power source 1035 may be a wired power source. Including power source 1035 on neckband 1005 instead of on eyewear device 1002 may help better distribute the weight and heat generated by power source 1035.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 1100 in FIG. 11, that mostly or completely covers a user's field of view. Virtual-reality system 1100 may include a front rigid body 1102 and a band 1104 shaped to fit around a user's head. Virtual-reality system 1100 may also include output audio transducers 1106(A) and 1106(B). Furthermore, while not shown in FIG. 11, front rigid body 1102 may include one or more electronic elements, including one or more electronic displays, one or more inertial measurement units (IMUS), one or more tracking emitters or detectors, and/or any other suitable device or system for creating an artificial-reality experience.

Artificial-reality systems may include a variety of types of visual feedback mechanisms. For example, display devices in augmented-reality system 1000 and/or virtual-reality system 1100 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 1000 and/or virtual-reality system 1100 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 1000 and/or virtual-reality system 1100 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

The preceding description has been provided to enable others skilled in the art to best utilize various aspects of the example embodiments disclosed herein. This example description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to any claims appended hereto and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

What is claimed is:

1. A display system, comprising:
a light source that emits input light having a wavelength within a source wavelength range;
an array of color conversion units overlapping a display area, wherein a first set of color conversion units of the array of color conversion units includes a first color conversion medium that converts the input light to a first color of light having a wavelength within a first wavelength range that is different than the source wavelength range; and
a waveguide that includes an out-coupler that directs the input light from the light source toward the array of color conversion units.

2. The display system of claim 1, wherein a second set of color conversion units of the array of color conversion units includes a second color conversion medium that converts the input light to a second color of light having a wavelength within a second wavelength range that is different than each of the first wavelength range and the source wavelength range.

3. The display system of claim 1, wherein the color conversion units are arrayed such that each color conversion unit overlaps a corresponding pixel of an array of pixels.

4. The display system of claim 1, wherein the input light comprises blue color light.

5. The display system of claim 4, wherein a third set of color conversion units of the array of color conversion units reflect the input light toward the display area without passing the input light through a color conversion medium.

6. The display system of claim 1, wherein the input light comprises ultraviolet light.

7. The display system of claim 1, wherein the waveguide overlaps the display area such that the waveguide is disposed between the display area and the array of color conversion units.

8. The display system of claim 1, further comprising a color filter layer overlapping the array of color conversion modules such that converted light passes through color filters of the color filter layer.

9. The display system of claim 1, further comprising an array of micro-focusing elements, wherein each micro-focusing element of the array of micro-focusing elements overlaps a corresponding color conversion unit of the array of color conversion units and directs a portion of the light from the waveguide toward the corresponding color conversion unit.

10. The display system of claim 1, wherein each color conversion unit of the array of color conversion units comprises at least a portion of a first reflective stack and at least a portion of a second reflective stack.

11. The display system of claim 10, wherein:
one of the first reflective stack and the second reflective stack comprises a highly reflective stack with respect to a broad range of wavelengths; and
the other of the first reflective stack and the second reflective stack comprises a partially reflective stack with respect to a narrower range of wavelengths that includes the source wavelength range.

12. The display system of claim 10, wherein:
one of the first reflective stack and the second reflective stack comprises a highly reflective stack with respect to a broad range of wavelengths; and
the other of the first reflective stack and the second reflective stack comprises a partially reflective stack with respect to a broad range of wavelengths.

13. The display system of claim 1, further comprising at least one polarizer disposed between the waveguide and the array of color conversion units.

14. The display system of claim 1, further comprising a light modulation layer disposed between the waveguide and the array of color conversion units.

15. The display system of claim 14, further comprising a common electrode disposed on a first side of the light modulation layer and an array of pixel electrodes disposed on an opposite side of the light modulation layer.

16. A color conversion unit, comprising:
a color conversion medium that converts input light having a wavelength within a source wavelength range to a first color of light having a wavelength within a first wavelength range that is different than the source wavelength range;
a first reflective stack disposed on a first side of the color conversion medium; and
a second reflective stack disposed on a second side of the color conversion medium, wherein at least one of the first reflective stack and the second reflective stack comprises a highly reflective stack with respect to a broad range of wavelengths.

17. The color conversion unit of claim 16, wherein the other of the first reflective stack and the second reflective stack comprises a partially reflective stack with respect to a range of wavelengths that includes the source wavelength range.

18. The color conversion unit of claim 16, wherein the other of the first reflective stack and the second reflective stack comprises a partially reflective stack with respect to a broad range of wavelengths.

19. The color conversion unit of claim 16, wherein at least one of the first reflective stack and the second reflective stack comprises a multilayer stack of alternating high- and low-index films.

20. A method, comprising:
supplying, by a waveguide, input light having a wavelength within a source wavelength range to an array of color conversion units, wherein a first set of color conversion units of the array of color conversion units includes a first color conversion medium;
converting, by the first set of color conversion units, the input light to a first color of light having a wavelength within a first wavelength range that is different than the source wavelength range; and
outputting, from the first set of color conversion units, the first color of light toward a display area.
